(19) United States
(12) Patent Application Publication
(10) Pub. No.: US 2022/0014699 A1
(43) Pub. Date: Jan. 13, 2022

(54) CHARGE SENSING DEVICE WITH READOUT OF SIGNAL BY DETECTING A CHANGE OF CAPACITANCE OF COMBINED GATE AND QUANTUM CAPACITANCE COMPARED TO A REFERENCE CAPACITANCE

(71) Applicants: FUNDACIÓ INSTITUT DE CIÈNCIES FOTÒNIQUES, Castelldefels (ES); INSTITUCIÓ CATALANA DE RECERCA I ESTUDIS AVANÇATS, Barcelona (ES)

(72) Inventors: Stijn Goossens, Castelldefels (ES); Frank Koppens, Castelldefels (ES); Gerasimos Konstantatos, Castelldefels (ES)

(73) Assignees: FUNDACIÓ INSTITUT DE CIÈNCIES FOTÒNIQUES, Castelldefels (ES); INSTITUCIÓ CATALANA DE RECERCA I ESTUDIS AVANÇATS, Barcelona (ES)

(21) Appl. No.: 17/427,507

(22) PCT Filed: Jan. 31, 2020
(86) PCT No.: PCT/EP2020/052450

§ 371 Date: Jul. 30, 2021

(30) Foreign Application Priority Data
Jan. 31, 2019 (EP) 19382068.5

(51) Int. Cl. H04N 5/378; H01L 31/108; H01L 31/113; H01L 27/146; G01R 27/26

(52) U.S. Cl. CPC H04N 5/378; H01L 31/108; G01R 27/2605; H01L 27/14643; H01L 31/1136

(57) ABSTRACT

The present invention relates to a system comprising an electronic apparatus which comprises: —an electronic device comprising: —a gate electrode structure (G, BE); —a dielectric (D) arranged over the gate electrode (G, BE); and —a charge sensing structure (CE) with a 2-dimensional charge sensing layer to provide a gate capacitance (C_{g}) between the charge sensing structure (CE) and the gate electrode structure (G, BE) and a quantum capacitance (C_{q}) resulting in a total capacitance (Cₜₒₜ); —a read-out circuit configured so that when the total capacitance (Cₜₒₜ) changes due to a change in the quantum capacitance (C_{q}), an imbalance between the total capacitance (Cₜₒₜ) and the reference capacitance (C_{f}) results in a change on the output voltage (Vₒ) that is amplified to provide the read-out signal (Sₒ). The present invention also relates to an electronic apparatus like the one of the system of the present invention.

### FIELD OF THE INVENTION

The present invention relates, in a first aspect, to a system comprising an electronic apparatus, comprising an electronic device constituting a capacitor that is used for charge sensing purposes and shows quantum capacitance, and a read-out circuit providing an improved read-out.

A second aspect of the present invention relates to an electronic apparatus like the one of the system of the first aspect of the invention, and adapted to allow the implementation of the improved read-out.

### BACKGROUND OF THE INVENTION

Systems which comprise the features of the preamble clause of claim 1 of the present invention are known in the art, i.e. those which comprise an electronic apparatus comprising:
an electronic device comprising:
   a gate electrode structure;
   a dielectric structure arranged over said gate electrode structure; and
   a charge sensing structure comprising at least one 2-dimensional charge sensing layer configured to sense electrical charges and/or electrical charge density changes induced by an external physical quantity, and that is configured and arranged over said dielectric structure to provide a gate capacitance C_{g} between the charge sensing structure and the gate electrode structure; wherein said charge sensing structure shows a quantum capacitance C_{g} in series with said gate capacitance C_{g} resulting in a total capacitance Cₜₒₜ between the charge sensing structure and the gate electrode structure;
a read-out circuit electrically connected to the charge sensing structure or to the gate electrode structure, to detect an output voltage Vₒ that is representative of said sensed electrical charges stored in said total capacitance Cₜₒₜ and provide a read-out signal based on the detected output voltage.

The following documents disclose different prior art electronic devices including a 2-dimensional charge sensing layer configured to sense electrical charges and/or electrical charge density changes induced by an external physical quantity:
Konstantatos, G., Badioli, M., Gaudreau, L. et al. Hybrid graphene-quantum dot phototransistors with ultrahigh gain. Nature Nanotech 7, 363-368 (2012).
Schedin, F., Geim, A., Morozov, S. et al. Detection of individual gas molecules adsorbed on graphene. Nature Mater 6, 652-655 (2007).
Wangyang Fu, Lingyan Feng, Gregory Panaitov, et al., Biosensing near the neutrality point of graphene, Science Advances 3, e1701247, (2017).

The read-out circuits of the systems of the prior art are clearly improvable. Therefore, it is necessary to provide an alternative to the state of the art, by providing a system including an improved read-out circuit which provides an improved reading of the read-out signal.

### SUMMARY OF THE INVENTION

To that end, the present invention relates, in a first aspect, to a system comprising an electronic apparatus, wherein the electronic apparatus comprises:
an electronic device comprising:
   a gate electrode structure;
   a dielectric structure arranged over said gate electrode structure; and
   a charge sensing structure comprising at least one 2-dimensional charge sensing layer configured to sense electrical charges and/or electrical charge density changes induced by an external physical quantity (for example, as described in the above cited prior art references), and that is configured and arranged over said dielectric structure to provide a gate capacitance C_{g} between the charge sensing structure and the gate electrode structure; wherein said charge sensing structure shows a quantum capacitance C_{g} in series with said gate capacitance C_{g} resulting in a total capacitance Cₜₒₜ between the charge sensing structure and the gate electrode structure;
a read-out circuit electrically connected to the charge sensing structure or to the gate electrode structure, to detect an output voltage Vₒ that is representative of said sensed electrical charges stored in said total capacitance Cₜₒₜ and provide a read-out signal based on the detected output voltage.

In contrast to the systems of the prior art, in the one proposed by the first aspect of the present invention, the read-out circuit comprises:
an amplifier with a first input electrically connected to the charge sensing structure or to the gate electrode structure to detect said output voltage and provide, at an output of the amplifier, said read-out signal;
a reference capacitor C_{ref} that has a magnitude equal to or differing at maximum a 50% with respect to said total capacitance Cₜₒₜ when there is no induced electrical charge or electrical charge carrier density on the charge sensing structure, wherein said reference capacitor C_{ref} has a first plate electrically connected to said first input of the amplifier; and
means configured and arranged to select and apply a control voltage to the one of said gate electrode structure and said charge sensing structure which is not electrically connected to the first input of the amplifier; wherein said control voltage is selected such that the fermi level of the charge sensing structure is tuned to the most sensitive point (i.e. around the charge neutrality point (cnp) when the 2-dimensional material is graphene), so that when said total capacitance Cₜₒₜ changes due to a change in the quantum capacitance C_{q} caused by an electrical charge or electrical charge carrier density induced on the charge sensing structure, an imbalance between the total capacitance Cₜₒₜ and the reference capacitance C_{ref} results in a change on the output voltage on the first input of the amplifier that is amplified to provide the read-out signal.

For an embodiment, the read-out circuit further comprises a first offset correction mechanism comprising said means which are configured and arranged to select and apply a first reference voltage to a second plate of the reference capacitor C_{ref}, so that the output voltage on the first input of the amplifier is zero when there is no induced electrical charge or electrical charge carrier density on the charge sensing structure.

For an embodiment, said means comprises at least one voltage source that generates at least said control voltage and, preferably, also the first reference voltage.

The terms “voltage source” must be interpreted in the present invention as any kind of real-world voltage source (i.e. with non-zero internal resistance and output impedance) known in the prior art, such as one comprising or formed by one or more battery cells, by one or more voltage generators, etc., for providing one (at least the above mentioned control voltage), two (the above mentioned control voltage and first reference voltage) or any number of voltages.

For an implementation of said embodiment, the output of the voltage source is electrically connected to the gate electrode structure or charge sensing structure, whether directly or through a switch, to apply the control voltage thereto, and, preferably to the second plate of the reference capacitor C_{ref}, whether directly or through a switch, to apply the control voltage thereto.

For a preferred embodiment, the above mentioned means comprises a control unit configured and arranged to select and apply at least the control voltage.

According to different embodiments, the control voltage is a DC voltage, an AC voltage, or a combination of DC and AC voltages (such as an AC voltage superimposed on a DC offset, or any kind of frequency and/or temporal combination).

For an embodiment, the control unit is configured to select the properties of the control voltage, at least regarding its magnitude, while for another embodiment for which the control voltage includes an AC voltage, the control unit is configured to select the properties of the control voltage also regarding its frequency and/or phase, and while for a further embodiment for which the control voltage includes an DC voltage, the control unit is configured to select the properties of the control voltage also regarding its polarity.

According to a further embodiment, the said read-out circuit further comprises a second offset correction mechanism comprising the above mentioned means which are configured and arranged to select and apply to a second input of the amplifier a second reference voltage with a magnitude equal or substantially equal to the output voltage when the charge sensitivity structure is set to its most sensitivity point and there is no electrical charge or electrical charge carrier density induced by the external physical quantity.

According to different embodiments, the first and/or second reference voltages is a DC voltage, an AC voltage, or a combination of DC and AC voltages.

For an embodiment, the control unit is configured to select the properties of the first and/or second reference voltage, at least regarding its magnitude, while for another embodiment for which the first and/or second reference voltage includes an AC voltage, the control unit is configured to select the properties thereof also regarding its frequency and/or phase.

For an embodiment, the read-out circuitry includes a reset circuit to discharge the total capacitance Cₜₒₜ, preferably under the control of the control unit.

The gate electrode structure together with the dielectric and charge sensing structures arranged there over, is arranged, for an embodiment, on a substrate.

According to an embodiment of the system of the first aspect of the present invention, the control unit further comprises an adjustment input connected to an output of the read-out circuit, and is configured to implement a closed-loop adjustment process to adjust the control voltage and/or the first and/or second reference voltage based on a read-out signal received through that adjustment input, and preferably also based on reference or set-point values with which the detected read-out signal(s) are compared. For an embodiment, the reference capacitor C_{ref} is a separate component (i.e. a component not implemented by the electronic device itself but electrically connected thereto), with respect to the electronic device, while for an alternative embodiment, the reference capacitor C_{ref} is implemented by the electronic device, with its first plate constituted by the charge sensing structure, a dielectric structure constituted by the sensitizing or functionalizing structure, and its second plate constituted by a top electrode structure arranged over the sensitizing or functionalizing structure.

According to an embodiment, electronic device and at least part of the read-out circuitry (for example an input transistor of the amplifier) are CMOS-implemented.

According to some embodiments, the electronic device of the electronic apparatus of the system of the first aspect of the present invention further comprises a sensitizing or functionalizing structure arranged over the charge sensing structure, wherein the sensitizing or functionalizing structure is configured to induce the electrical charge carriers and/or modify the charge carrier density therein induced by said external physical quantity. Generally the sensitizing or functionalizing structure is only sensitive to said external physical quantity.

The term “functionalizing” means for the present invention, to add a species to the charge sensing structure that not only provides a sensitizing function, but also adds another functionality. For example, in the paper by Wangyang Fu (Wangyang Fu, Lingyan Feng, Gregory Panaitov, et al., Biosensing near the neutrality point of graphene, Science Advances 3, e1701247, (2017).) a pPNA linker molecule is added to the surface of the graphene to allow ssDNA to link to the graphene and a Tween 20 molecule was added to the graphene surface to make the sensing of the ssDNA more specific by inhibiting attachment of other species to the surface of the graphene. Hence in this case the pPNA linker molecule functionalizes AND sensitizes the graphene.

While the term “sensitizing” refers to any species that is added on top of the charge sensing structure that sensitizes it to an external physical quantity or analyte.

For an embodiment, said sensitizing or functionalizing structure is a photoactive structure configured and arranged to, upon illumination, generate electron-hole pairs which, due to a field created by either a Schottky junction between the charge sensing structure and the photoactive structure or a top gate electrode on top of the photoactive structure or an interlayer between the charge sensing structure and the photoactive structure, are separated and either the electrons or holes gets transported, as said induced electrical charge carriers, to the charge sensing structure, so that the optoelectronic apparatus constitutes a photodetector or an image sensor.

For an implementation of that embodiment, the system of the first aspect of the present invention implements an image sensor comprising an array of pixels, wherein the electronic apparatus comprises a plurality of the above mentioned electronic devices each constituting one pixel of said array of pixels, implementing different alternative read-out schemes, for addressing and reading the pixels of the rows and columns of the array, including rolling and global shutter, etc.

According to an alternative embodiment, the electronic device is absent of any sensitizing or functionalizing structure arranged over the charge sensing structure, the charge sensing structure being configured to undergo a change in the electrical charge carriers and/or modify the charge carrier density therein induced by the external physical quantity.

Therefore, the present invention is generally applied to sensing devices that rely sensing a change in the electrical charge carriers and/or in the charge carrier density in the charge sensing structure induced by said external physical quantity, whether directly on an exposed charge sensing structure, through the intermediation of a sensitizing layer (such as a photo-sensitizing layer, for example made up of PbS colloidal quantum dots, where light can induce the charge carriers in the charge sensing structure, or a linker biomolecule grafted on the charge sensing structure) or through the functionalization of the charge sensing structure (e.g. for biosensing).

The charge sensing structure of the electronic device of the electronic apparatus of the system of the first aspect of present invention comprises one or more 2-dimensional charge sensing layers made of, for example, one or more of the following materials: single or few layer graphene (pure graphene, modified graphene, or functionalized graphene), black phosphorus, MoS₂, WS₂, WSe₂, etc.

Different physical quantities or analytes can be sensed by the electronic apparatus of the system of the first aspect of the invention, as long as they induce electrical charge carriers in the charge sensing structure and/or a change in the charge carrier density therein, such as light, gas molecules or sensing neuronal signals. The analyte of interest transfers charge to the charge sensing structure or induces an electric field that modifies the charge carrier density thereof.

Another application is for direct sensing of in vivo electrical signals, or for implementing biosensors using chemically bonded linker molecules that enhance the selectivity for specific bio-molecules. When the molecule of interest binds to the linker, it transfer charge to the charge sensing structure or induces an electric field therein that modifies its charge carrier density.

A second aspect of the present invention relates to an electronic apparatus, comprising:
a gate electrode structure;
a dielectric structure arranged over said gate electrode structure; and
a charge sensing structure comprising at least one 2-dimensional charge sensing layer configured to sense electrical charges and/or electrical charge density changes induced by an external physical quantity, and that is configured and arranged over said dielectric structure to provide a gate capacitance C_{g} between the charge sensing structure and the gate electrode structure; wherein said charge sensing structure shows a quantum capacitance C_{q} in series with said gate capacitance C_{g} resulting in a total capacitance Cₜₒₜ between the charge sensing structure and the gate electrode structure;
a read-out circuit electrically connected to the charge sensing structure or to the gate electrode structure, to detect an output voltage Vₒ that is representative of said sensed electrical charges stored in said total capacitance Cₜₒₜ and provide a read-out signal Sₒ based on the detected output voltage.

In contrast to the electronic apparatuses of the prior art, in the one of the second aspect of the present invention the read-out circuit comprises:
an amplifier with a first input electrically connected to the charge sensing structure or to the gate electrode structure, to detect the output voltage and provide, at an output of the amplifier, said read-out signal; and
a reference capacitor C_{ref} that has a magnitude equal to or differing at maximum a 50% with respect to said total capacitance Cₜₒₜ when there is no induced electrical charge or electrical charge carrier density on the charge sensing structure, wherein said reference capacitor C_{ref} has a first plate electrically connected to said first input of the amplifier;

and in that the electronic apparatus further comprises at least a first input terminal electrically connected to the one of said gate electrode structure and said charge sensing structure which is not electrically connected to the first input of the amplifier;

wherein said first input terminal is accessible to apply thereto a control voltage which is selected such that the fermi level of the charge sensing structure is tuned to the most sensitive point;

so that when said total capacitance Cₜₒₜ changes due to a change in the quantum capacitance C_{q} caused by an electrical charge or electrical charge carrier density induced on the charge sensing structure, an imbalance between the total capacitance Cₜₒₜ and the reference capacitance C_{ref} results in a change on the output voltage Vₒ on the first input of the amplifier that is amplified to provide the read-out signal Sₒ.

The embodiments described in the present document regarding the electronic apparatus of the system of the first aspect of the present invention are valid for describing corresponding embodiments of the electronic apparatus of the second aspect of the present invention.

### BRIEF DESCRIPTION OF THE FIGURES

In the following some preferred embodiments of the invention will be described with reference to the enclosed figures. They are provided only for illustration purposes without however limiting the scope of the invention.

FIG. 1 schematically shows the system of the first aspect of the present invention, for a first embodiment;

FIG. 2 schematically shows the system of the first aspect of the present invention, for a second embodiment;

FIG. 3 schematically shows a Si-CMOS implementation of the electronic device and part of the readout-circuitry of the electronic apparatus of the system of the first aspect of the present invention, for the arrangement of the second embodiment;

FIG. 4 schematically shows the system of the first aspect of the present invention, for a third embodiment;

FIG. 5 is a schematic side view of the structure of the electronic device of the electronic apparatus of the second aspect of the invention and of the electronic apparatus of the system of the first aspect, for an embodiment, with electrical connections indicated as round circles: CE=charge sensing layer electrode and BE=bottom electrode.

FIG. 6 is a schematic side view of the of the electronic device of the electronic apparatus of the second aspect of the invention and of the electronic apparatus of the system, for an embodiment for which the electronic device comprises a photoactive structure for, upon illumination, generate electron-hole pairs which are separated and one of them gets transported to the charge sensing structure (CE), as indicated by the charge flow illustrated.

### DESCRIPTION OF THE PREFERRED EMBODIMENTS

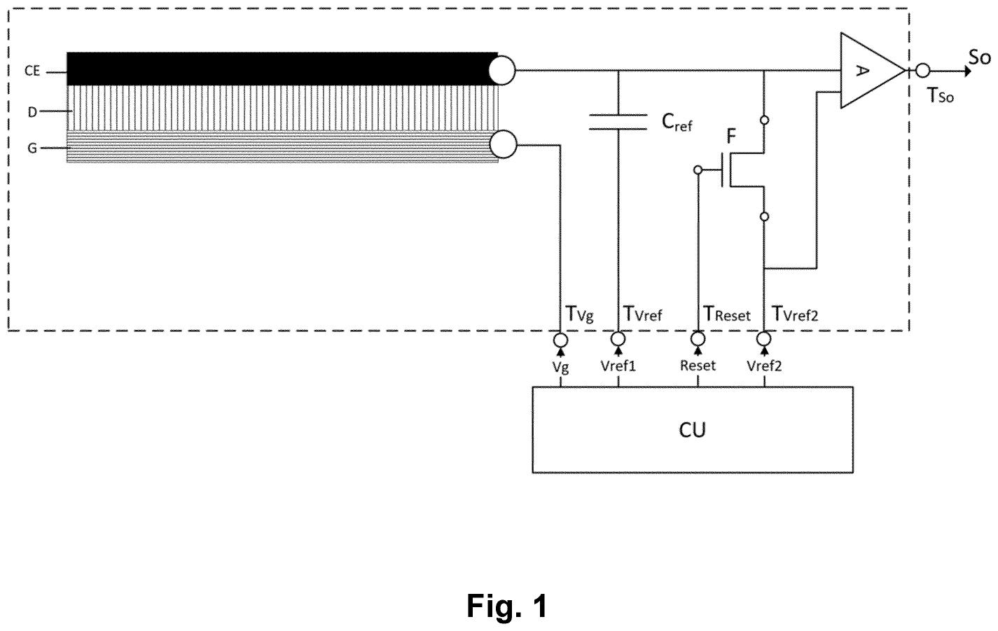

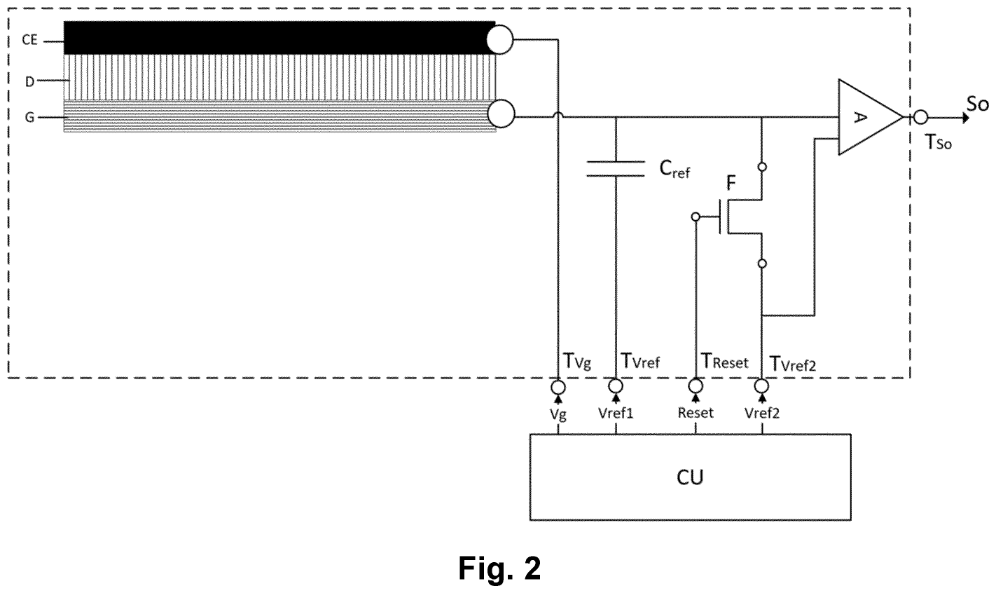

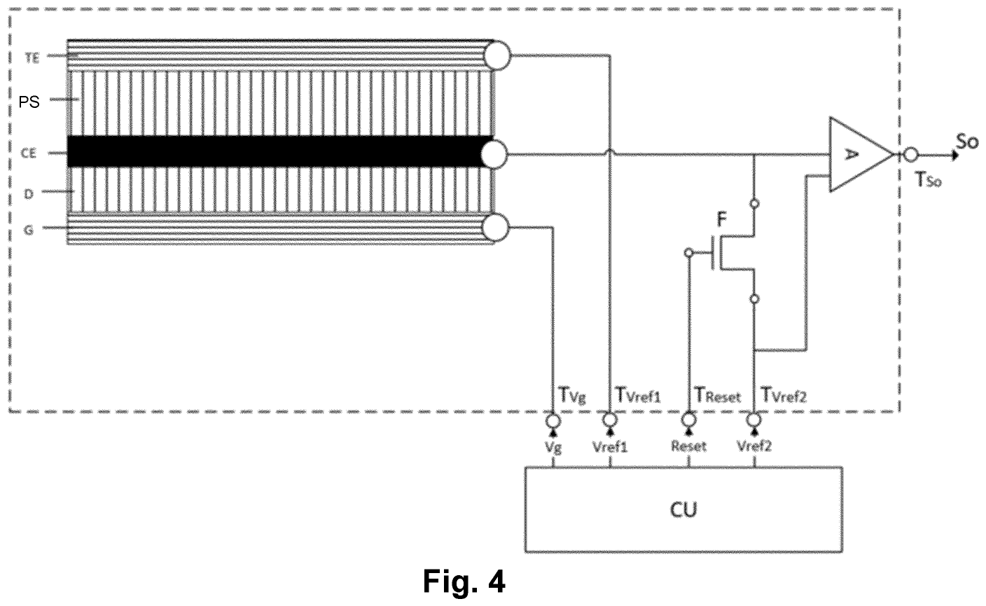

FIGS. 1, 2, and 4 show respective first, second and third embodiments of the system of the present invention, for which the electronic apparatus thereof comprises:
an electronic device forming a capacitive sensing device (CSD), comprising:
   a gate electrode structure G;
   a dielectric structure D arranged over the gate electrode structure G; and
   a charge sensing structure CE comprising at least one 2-dimensional charge sensing layer configured to sense electrical charges and/or electrical charge density changes induced by an external physical quantity, and that is configured and arranged over said dielectric structure D to provide a gate capacitance C_{g} between the charge sensing structure CE and the gate electrode structure G; wherein said charge sensing structure CE shows a quantum capacitance C_{g} in series with said gate capacitance C_{g} resulting in a total capacitance Cₜₒₜ between the charge sensing structure CE and the gate electrode structure G;
a read-out circuit electrically connected to the charge sensing structure CE (for FIGS. 1 and 4) or to the gate electrode structure G (for FIG. 2), to detect an output voltage Vₒ that is representative of the sensed electrical charges stored in the total capacitance Cₜₒₜ and provide a read-out signal Sₒ based on the detected output voltage Vₒ.

As shown in those figures, the read-out circuit comprises:
an amplifier A with a first input electrically connected to the charge sensing structure CE (for FIGS. 1 and 4) or to the gate electrode structure G (for FIG. 2) to detect the output voltage Vₒ and provide, at an output of the amplifier A, the read-out signal S₀;
a reference capacitor C_{ref} that has a magnitude equal to or differing at maximum a 50% with respect to said total capacitance Cₜₒₜ when there is no induced electrical charge or electrical charge carrier density on the charge sensing structure CE, wherein the reference capacitor C_{ref} has a first plate electrically connected to the first input of the amplifier A; and
means comprising a control unit CU configured and arranged to select and apply a control voltage V_{g} to the one of the gate electrode structure G (for FIGS. 1 and 4) and the charge sensing structure CE (for FIG. 2) which is not electrically connected to the first input of the amplifier A; wherein the control voltage V_{g} is selected such that the fermi level of the charge sensing structure CE is tuned to the most sensitive point,

so that when said total capacitance Cₜₒₜ changes due to a change in the quantum capacitance C_{g} caused by an electrical charge or electrical charge carrier density induced on the charge sensing structure CE, an imbalance between the total capacitance Cₜₒₜ and the reference capacitance C_{ref} results in a change on the output voltage Vₒ on the first input of the amplifier A that is amplified to provide the read-out signal Sₒ.

As shown FIGS. 1, 2 and 4, the read-out circuit further comprises a first offset correction mechanism comprising the control unit CU which is configured and arranged to select and apply a first reference voltage V_{ref1} to a second plate of the reference capacitor C_{ref}, so that the output voltage Vₒ on the first input of the amplifier A is zero when there is no induced electrical charge or electrical charge carrier density on the charge sensing structure CE.

Also, for the embodiments illustrated in FIGS. 1, 2 and 4, the read-out circuit further comprises a second offset correction mechanism comprising the control unit CU which is configured and arranged to select and apply to a second input of the amplifier A a second reference voltage V_{ref2} with a magnitude equal or substantially equal to the output voltage Vₒ when the charge sensitivity structure CE is set to its most sensitive point and there is no electrical charge or electrical charge carrier density induced by the external physical quantity.

As shown in FIGS. 1, 2 and 4, the read-out circuit comprises a reset circuit, formed by a transistor F, to discharge the total capacitance Cₜₒₜ under the control of the control unit CU (by closing the transistor F so as to connect CE or G to V_{ref2}), when the illustrated Reset signal is applied thereto.

The classical capacitance of the CSD is given by the following formula:

C_{g}=εᵣε₀A/d

Where εᵣ is the relative permittivity of the dielectric material, ε₀ is the vacuum permittivity, A the area of the capacitor and d the thickness of the dielectric material.

For 2-dimensional materials there is another capacitance that needs to be taken into account due to their finite density of states. This is the quantum capacitance C_{q}. C_{q} is in series with the classical capacitance and thus reduces the total capacitance Cₜₒₜ of the system (1/Cₜₒₜ=1/C_{g}+1/C_{q}). The quantum capacitance is in general a function of the fermi level in the system, so it can be tuned by an external electric field, or a charge induced in the system by an external physical quantity.

When the 2-dimensional material is graphene, the quantum capacitance per unit area C_{q}/A is described as follows:

$${C}_{Q} = \frac{2 {e}^{2}}{ℏ {v}_{F} \sqrt{π}} {( \vert {n}_{G} \vert + \vert {n}^{*} \vert )}^{1 / 2}$$

Where e is the electron charge, h the planck constant, v_{F} the Fermi velocity of graphene, n_{G} the induced carrier density in the graphene and n* the residual impurity density.

When Cₜₒₜ changes due to the charge or charge carrier density induced on the charge sensing electrode, an imbalance in the capacitor system results in a voltage change Vₒ on the input of the amplifier A.

Vₒ=Cₜₒₜ/(C_{ref}+Cₜₒₜ)*(V_{g}−V_{ref1})+V_{ref1}

Amplifier A then amplifies the output voltage Vₒ to output signal Sₒ.

In case the sensing electrode is made up of (few layer) graphene, this is at the charge neutrality point or dirac point. The output voltage Vₒ of the structure is measured by the amplifier A with respect to V_{ref2}. V_{ref2} needs to be set such that it is equal (or substantially equal) to the output voltage Vₒ when the charge sensing electrode CE is set to its most sensitive point and there is no charge or charge carrier density induced by the external physical quantity.

For the third embodiment, i.e. that illustrated in FIG. 4, the electronic device further comprises a sensitizing or functionalizing structure PS arranged over the charge sensing structure CE, wherein said sensitizing or functionalizing structure PS is configured to induce said electrical charges and/or modify the electrical charge carrier density therein induced by said external physical quantity, wherein the sensitizing or functionalizing structure PS is only sensitive to said external physical quantity.

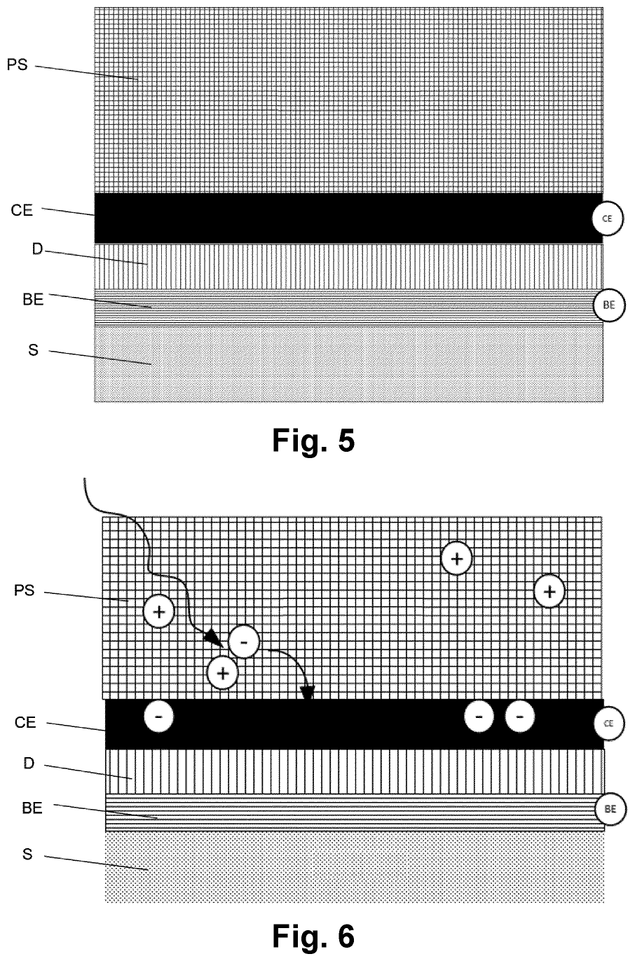

The stacked up structure of the electronic device of said third embodiment is shown in FIGS. 5 and 6, for an implementation for which the electronic device is a photodetector which comprises a substrate S, a bottom electrode structure BE (as the above mentioned gate electrode structure), and a sensitizing or functionalizing structure PS constituted by a photoactive structure PS (formed by colloidal quantum dots, III-V semiconductor, perovskites, 2D material, etc.) arranged over the charge sensing structure CE (for example, formed by a single layer or few layer graphene, black phosphorus, MoS₂, WS₂, WSe₂ etc.) configured and arranged to, upon illumination, generate electron-hole pairs which, due to a built-in field created by a Schottky junction between the charge sensing structure CE and the photoactive structure PS, are separated and either the electrons or holes (depending on the type of Schottky junction) gets transported to the charge sensing structure CE. A voltage now builds up on the gate capacitor C_{g}. In case of a photosensitive layer it is the total photogenerated charge: Qₚₕ=EQE*qₑ*τₜᵣ A/Eₚ I, (EQE is the external quantum efficiency, qₑ the electron charge, τₜᵣ the trapping time of the photogenerated charges and I the irradiance, A the area of the device and Eₚ the photon energy). This process is illustrated in FIG. 6.

Also for the third embodiment, as shown in FIG. 4, the reference capacitor C_{ref} is implemented by the electronic device, with its first plate constituted by the charge sensing structure CE, a dielectric structure constituted by the sensitizing or functionalizing structure PS, and its second plate constituted by a top electrode structure TE arranged over the sensitizing or functionalizing structure PS.

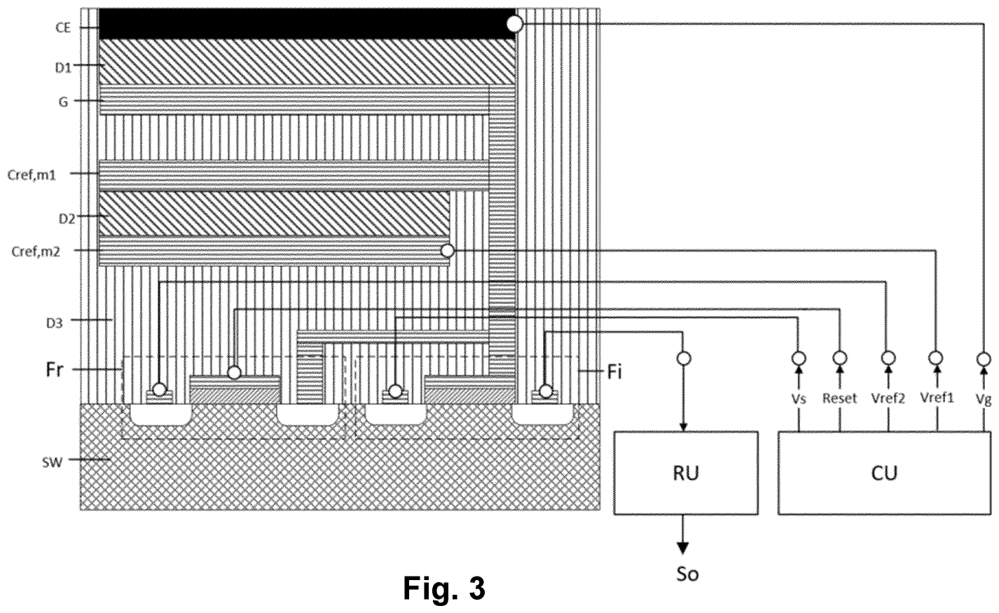

The layout of the second embodiment, illustrated in FIG. 2, can have advantages for integration in complementary metal oxide semiconductor devices. Hence, FIG. 3 shows a possible CMOS implementation of the electronic device and part of the readout-circuit (particularly, an input transistor Fi of the amplifier A) of the electronic apparatus of the system of the first aspect of the present invention, for the arrangement of the second embodiment. The rest of the read-out circuit is depicted by means of block RU.

In FIG. 3 is shown how on a silicon wafer (SW) field effect transistors Fr (the reset transistor F) and Fi (the input transistor of the amplifier A) are implemented. In a layer above, the reference capacitor C_{ref} is implemented with two metal layers, namely C_{ref,m1} and C_{ref,m2}, and a dielectric layer (D2). Above the reference capacitor C_{ref} the capacitive sensing device (CSD) is implemented. C_{ref,m1}, G and the gate electrode of Fi are connected via a vertical metal connection. The structures are embedded in a dielectric D3. A control unit CU provides the necessary signals described in embodiment 1 and moreover provides Vs to bias transistor Fi in the proper way. The drain of transistor Fi is connected to read-out unit RU that further amplifies and processes the signal to provide finally output signal Sₒ that is proportional to the electrical charge or charge carrier density on CE induced by the external physical quantity.

FIGS. 1, 2 and 4 also show respective embodiments of the electronic apparatus of the second aspect of the present invention which comprises the components depicted within or in contact with the contour of the dotted-line squares (which can be embedded in an integrated circuit), i.e. the components of the electronic apparatus of the system of the first aspect of the present invention and further input pin terminals TV_{g}, T_{vref1}, T_{Reset} and T_{vref1}, and also an output pin connected to terminal TSₒ, so that a control unit CU can be connected to those input pin terminals to provide voltages V_{g}, V_{ref1}, V_{ref2} and Reset signal, while Sₒ goes out through output terminal TSₒ. For some embodiments, the control unit CU is also integrated in the integrated circuit.

A person skilled in the art could introduce changes and modifications in the embodiments described without departing from the scope of the invention as it is defined in the attached claims.

1. A system comprising an electronic apparatus, wherein the electronic apparatus comprises:
an electronic device comprising:
a gate electrode structure;
a dielectric structure arranged over said gate electrode structure; and
a charge sensing structure comprising at least one 2-dimensional charge sensing layer configured to sense electrical charges and/or electrical charge density changes induced by an external physical quantity, and that is configured and arranged over said dielectric structure to provide a gate capacitance between the charge sensing structure and the gate electrode structure; wherein said charge sensing structure shows a quantum capacitance in series with said gate capacitance resulting in a total capacitance between the charge sensing structure and the gate electrode structure; and
a read-out circuit electrically connected to the charge sensing structure or to the gate electrode structure, to detect an output voltage that is representative of said sensed electrical charges stored in said total capacitance and provide a read-out signal based on the detected output voltage;
wherein said read-out circuit comprises:
an amplifier with a first input electrically connected to the charge sensing structure or to the gate electrode structure to detect said output voltage and provide, at an output of the amplifier, said read-out signal;
a reference capacitor that has a magnitude equal to or differing at maximum a 50% with respect to said total capacitance when there is no induced electrical charge or electrical charge carrier density on the charge sensing structure, wherein said reference capacitor has a first plate electrically connected to said first input of the amplifier; and
a mechanism configured and arranged to select and apply a control voltage to the one of said gate electrode structure and said charge sensing structure which is not electrically connected to the first input of the amplifier; wherein said control voltage is selected such that the fermi level of the charge sensing structure is tuned to the most sensitive point;
so that when said total capacitance changes due to a change in the quantum capacitance caused by an electrical charge or electrical charge carrier density induced on the charge sensing structure, an imbalance between the total capacitance and the reference capacitance results in a change on the output voltage on the first input of the amplifier that is amplified to provide the read-out signal.

2. The system of claim 1, wherein the read-out circuit further comprises a first offset correction mechanism comprising said mechanism, which are configured and arranged to select and apply a first reference voltage to a second plate of the reference capacitor, so that the output voltage on the first input of the amplifier is zero when there is no induced electrical charge or electrical charge carrier density on the charge sensing structure.

3. The system of claim 1, wherein said mechanism comprises at least one voltage source that generates at least said control voltage.

4. The system of claim 1, wherein said mechanism comprises a control unit configured and arranged to select and apply at least said control voltage.

5. The system of claim 4, wherein said control voltage is a DC voltage, an AC voltage, or a combination of DC and AC voltages, and wherein the control unit is configured to select the properties of said control voltage, at least regarding its magnitude.

6. The system of claim 1, wherein said read-out circuit further comprises a second offset correction mechanism comprising said mechanism, which is configured and arranged to select and apply to a second input of the amplifier a second reference voltage with a magnitude equal or substantially equal to the output voltage when the charge sensitivity structure is set to its most sensitivity point and there is no electrical charge or electrical charge carrier density induced by the external physical quantity.

7. The system of claim 4, wherein said read-out circuit further comprises a second offset correction mechanism comprising said mechanism, which are configured and arranged to select and apply to a second input of the amplifier a second reference voltage with a magnitude equal or substantially equal to the output voltage when the charge sensitivity structure is set to its most sensitivity point and there is no electrical charge or electrical charge carrier density induced by the external physical quantity, and wherein said control unit is also configured and arranged to select and apply said second reference voltage.

8. The system of claim 1, wherein said read-out circuitry further comprises a reset circuit to discharge the total capacitance.

9. The system according to claim 1, wherein the electronic device further comprises a sensitizing or functionalizing structure arranged over said charge sensing structure, wherein said sensitizing or functionalizing structure is configured to induce said electrical charges and/or modify the electrical charge carrier density therein induced by said external physical quantity, wherein the sensitizing or functionalizing structure only sensitive to said external physical quantity.

10. The system of claim 1, wherein said reference capacitor is a separate component, with respect to the electronic device.

11. The system of claim 9, wherein said reference capacitor is implemented by the electronic device, with said first plate constituted by said charge sensing structure, a dielectric structure constituted by said sensitizing or functionalizing structure, and said second plate constituted by a top electrode structure arranged over said sensitizing or functionalizing structure.

12. The system of claim 1, wherein the electronic device and at least part of the read-out circuitry are CMOS-implemented.

13. The system of claim 9, wherein said sensitizing or functionalizing structure is a photoactive structure configured and arranged to, upon illumination, generate electron-hole pairs which, due to a field created by either a Schottky junction between the charge sensing structure and the photoactive structure or a top electrode structure on top of the photoactive structure or an interlayer between the charge sensing structure and the photoactive structure, are separated and either the electrons or holes gets transported, as said induced electrical charge carriers, to the charge sensing structure.

14. The system according to claim 13, implementing an image sensor comprising an array of pixels, wherein the electronic apparatus comprises a plurality of said electronic devices each constituting one pixel of said array of pixels.

15. An electronic apparatus, comprising:
an electronic device comprising:
a gate electrode structure;
a dielectric structure arranged over said gate electrode structure; and
a charge sensing structure comprising at least one 2-dimensional charge sensing layer configured to sense electrical charges and/or electrical charge density changes induced by an external physical quantity, and that is configured and arranged over said dielectric structure to provide a gate capacitance between the charge sensing structure and the gate electrode structure; wherein said charge sensing structure shows a quantum capacitance in series with said gate capacitance between the charge sensing structure and the gate electrode structure; and
a read-out circuit electrically connected to the charge sensing structure or to the gate electrode structure, to detect an output voltage that is representative of said sensed electrical charges stored in said total capacitance and provide a read-out signal based on the detected output voltage;
wherein said read-out circuit comprises:
an amplifier with a first input electrically connected to the charge sensing structure or to the gate electrode structure, to detect said output voltage and provide, at an output of the amplifier, said read-out signal; and
a reference capacitor that has a magnitude equal to or differing at maximum a 50% with respect to said total capacitance when there is no induced electrical charge or electrical charge carrier density on the charge sensing structure, wherein said reference capacitor has a first plate electrically connected to said first input of the amplifier;
and in that further wherein the electronic apparatus further comprises at least a first input terminal electrically connected to the one of said gate electrode structure and said charge sensing structure which is not electrically connected to the first input of the amplifier;
wherein said first input terminal is accessible to apply thereto a control voltage which is selected such that the fermi level of the charge sensing structure is tuned to the most sensitive point;
so that when said total capacitance changes due to a change in the quantum capacitance caused by an electrical charge or electrical charge carrier density induced on the charge sensing structure, an imbalance between the total capacitance and the reference capacitance results in a change on the output voltage on the first input of the amplifier that is amplified to provide the read-out signal.
